(19) United States
(12) Patent Application Publication
(10) Pub. No.: US 2003/0211743 A1
(43) Pub. Date: Nov. 13, 2003

(54) Method for avoiding slurry sedimentation in CMP slurry delivery systems

(75) Inventors: Chao-Jung Chang, Hsin-Chu (TW); Ping-Hsu Chen, Hsin-Chu (TW); Jui-Cheng Lo, Hsin-Chu (TW); Ping Chuang, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/140,727

(22) Filed: May 7, 2002

(51) Int. Cl. H01L 21/461; B44C 1/22

(52) U.S. Cl. 438/692; 216/38; 156/345.12

(57) ABSTRACT

A method for preventing deposition of abrasive particles included in a surfactant containing slurry along flow pathways in a chemical mechanical polishing (CMP) slurry delivery system including providing a CMP delivery system having one or more flow pathways for delivering a surfactant containing slurry to at least one polishing station the surfactant containing slurry including abrasive particles; providing at least a fluid contact portion of the one or more flow pathways including at least flow pathway feed lines with a dipole inactive material for contacting the surfactant containing slurry; and, controllably delivering the surfactant containing slurry along the flow pathway feed lines to the at least one polishing station to perform a CMP process.

### FIELD OF THE INVENTION

This invention generally relates to chemical mechanical polishing (CMP) and more particularly to a method and apparatus for CMP slurry delivery for avoiding slurry adhesion and sedimentation in CMP slurry delivery systems.

### BACKGROUND OF THE INVENTION

In semiconductor fabrication integrated circuits and semiconducting devices are formed by sequentially forming features in sequential layers of material in a bottom-up manufacturing method. The manufacturing process utilizes a wide variety of deposition techniques to form the various layered features including various etching techniques such as anisotropic plasma etching to form device feature openings followed by deposition techniques to fill the device features. In order to form reliable devices, close tolerances are required in forming features including photolithographic patterning methods which rely heavily on layer planarization techniques to maintain a proper depth of focus.

Planarization is increasingly important in semiconductor manufacturing techniques. As device sizes decrease, the importance of achieving high resolution features through photolithographic processes correspondingly increases thereby placing more severe constraints on the degree of planarity required of a semiconductor wafer processing surface. Excessive degrees of surface nonplanarity will undesirably affect the quality of several semiconductor manufacturing process including, for example, photolithographic patterning processes, where the positioning the image plane of the process surface within an increasingly limited depth of focus window is required to achieve high resolution semiconductor feature patterns.

Chemical mechanical polishing (CMP) is increasingly being used as a planarizing process for semiconductor device layers, especially for devices having multi-level design and smaller semiconductor fabrication processes, for example, below about 0.25 micron. CMP planarization is typically used several different times in the manufacture of a multi-level semiconductor device, including planarizing levels of a device containing both dielectric and metal portions to achieve global planarization for subsequent processing of overlying levels. For example, in a shallow trench isolation (STI) manufacturing process CMP is used to remove excess silicon oxide deposited by, for example, a high density plasma chemical vapor deposition (HDP-CVD) process to back fill (STI) trenches.

STI features with trenches having submicrometer dimensions are formed around active areas of a CMOS device to electrically isolate the active area. In the STI manufacturing technique, the STI features are created by first anisotropically etching STI trenches into the silicon substrate through overlying layers including a pad oxide layer and a hardmask metal nitride layer, for example silicon nitride, overlying the pad oxide layer. The STI trench is then typically lined with a thermally grown silicon dioxide layer, also referred to as an oxide trench liner, grown over the exposed silicon substrate forming the trench surfaces. The STI trench is then back filled with a chemical vapor deposited (CVD) silicon oxide and chemically mechanically polished (CMP) back to the hardmask layer which also functions as a CMP polish stop layer to form a planar surface. During the STI CMP process, it is important to achieve a high degree of planarity while removing a relatively thick layer of silicon oxide. High selectivity CMP polishing slurries including abrasives such as CeO₂ and MnO₂ particles are increasingly finding application in the STI CMP process where STI feature widths are approaching 0.1 micron. The high selectivity metal oxide slurries are preferred since they have higher oxide removal rates compared to SiO₂ with improved polishing selectivity to the oxide versus the hardmask layer together with minimal surface scratching. In addition, some methods of STI manufacture dispense with the hardmask layer due to the improved selectivity of high selectivity slurries in oxide polishing versus silicon. Due to the tendency of high selectivity polishing slurries to agglomerate, it is necessary to add surfactants to the slurry solution to prevent agglomeration of the slurry particles thereby maintaining good particle dispersion.

In a typical CMP polishing or planarization process, the wafer is typically pressed against a rotating polishing pad. In addition, the wafer may rotate and oscillate over the surface of the polishing pad to improve polishing effectiveness. The slurry is typically introduced from a slurry reservoir through a piping system to a nozzle or sprayer where it is applied to the polishing pad to subsequently contact the wafer polishing surface. Alternatively, the slurry may be fed through a feed system directly through the lower portion of the polishing pad.

As feature sizes decrease, the ability to achieve both global and local planarization in CMP processes is increasingly critical. CMP polishing generally tends to preferentially polish smaller features having a higher surface density, making polishing selectivity and planarization critical in, for example, STI features where STI trench widths are approaching the order of 0.1 micron. As a result, slurries having high selectivity metal oxide abrasives such as CeO₂ and MnO₂ to achieve higher material removal rates with minimal surface scratching while providing good planarity are increasingly preferred. One drawback to the use of such high selectivity metal oxides is the necessity of adding surfactants to the slurry to maintain slurry particle dispersion.

A major problem with surfactant containing slurries is the tendency of the surfactant to induce slurry interaction with the slurry delivery system including the feed lines or piping. The CMP slurry delivery system, in operation, typically includes feeding the slurry components through tubing or feed lines to one or more mixers to precisely mix and blend the slurries prior to delivery through additional feed lines to one or more polishing pads for wafer polishing. The surfactant containing slurries have been found to preferentially deposit on the walls of the feed lines in the distribution system thereby potentially contaminating one slurry recipe with another or altering the mixing ratio. For example, mixing ratios of the abrasives and various additives may be detrimentally altered with contaminating feed line deposits to cause unpredictable variability in the CMP polishing process necessitating frequent CMP apparatus downtime for cleaning.

Therefore, there is a need in the semiconductor art to develop an improved method and CMP delivery system for surfactant containing slurries in a CMP process to avoid slurry interaction with the delivery system thereby causing slurry deposits in the slurry delivery system.

It is therefore an object of the invention to provide

an improved method and CMP delivery system for surfactant containing slurries in a CMP process to avoid slurry interaction with the delivery system thereby causing slurry deposits in the slurry delivery system while overcoming other shortcomings and deficiencies in the prior art.

### SUMMARY OF THE INVENTION

To achieve the foregoing and other objects, and in accordance with the purposes of the present invention, as embodied and broadly described herein, the present invention provides a method for preventing deposition of abrasive particles included in a surfactant containing slurry along flow pathways in a chemical mechanical polishing (CMP) slurry delivery system. Another aspect of the invention provides a CMP slurry delivery system for preventing deposition of abrasive particles included in a surfactant containing slurry along a delivery flow pathway.

In a first embodiment of the invention, the method includes providing a CMP delivery system having one or more flow pathways for delivering a surfactant containing slurry to at least one polishing station the surfactant containing slurry including abrasive particles; providing at least a fluid contact portion of the one or more flow pathways including at least flow pathway feed lines with a dipole inactive material for contacting the surfactant containing slurry; and, controllably delivering the surfactant containing slurry along the flow pathway feed lines to the at least one polishing station to perform a CMP process.

In a second embodiment of the invention, the CMP slurry delivery system includes one or more polishing solution containers having respective first flow pathways in parallel fluidic communication with a mixing container for mixing a surfactant containing slurry for delivery said mixing container having a second flow pathway in series fluidic communication with a slurry delivery member for delivering the surfactant containing slurry to contact a polishing pad at least a portion of at least one of said first flow pathways and said second flow pathway including a dipole inactive material for contacting the surfactant containing slurry to prevent particle deposition.

These and other embodiments and features of the invention will be better understood from a detailed description of the preferred embodiments of the invention which are further described below in conjunction with the accompanying Figures.

### BRIEF DESCRIPTION OF THE DRAWINGS

FIG. 1 is a perspective view of an exemplary CMP polishing apparatus for use with the method and CMP slurry delivery system according to an embodiment of the present invention.

FIG. 2 is a schematic diagram of an exemplary CMP slurry delivery system according to one embodiment of the present invention.

### DETAILED DESCRIPTION OF THE PREFERRED EMBODIMENTS

While the method according to the present invention is explained primarily with reference to an STI CMP process involving high selectivity slurries it will be appreciated that the method and CMP delivery system of the present invention may be advantageously applied to any CMP delivery system where surfactant containing slurries are used. By the term ‘surfactant’ as used herein in meant any chemical additive including a cationic, anionic, or nonionic surfactant where the chemical structure includes at least one hydrophilic group and at least one hydrophobic group.

The term “particle” as it is used herein refers to both agglomerates of more than one primary particle and to single primary particles. The term “mean particle diameter” as used herein refers to the mean diameter of the primary particle whether agglomerated with other primary particles or not. By the term “mean particle diameter” is meant a mean diameter taken from a statistically significant sampling of the average equivalent spherical diameter of primary particles when using TEM image analysis.

In one embodiment of the present invention, a dipole inactive material is used in at least a portion of the CMP delivery system. Preferably, the dipole inactive material is used through out the CMP delivery system. For example, the delivery system may include holding containers, feed lines, mixers, and nozzles.

It has been found that surfactant containing slurries interact with dipole active materials causing adhesion or sedimentation of the abrasive particles in the surfactant containing slurry. By ‘dipole active’ materials are meant materials including a repeating chemical group where an electric dipole is present as a portion of the repeating chemical group. For example, oxygen containing plastics and polymers are frequently dipole active. For example, a polymer frequently used for tubing or containers includes PFA (perfluoroalkoxy) which is dipole active. It has been found that dipole inactive materials are resistant to abrasive sedimentation and adhesion in surfactant containing slurries. For example, among dipole inactive materials, polytetrafluoroethylene (PTFE) is preferred for use in a CMP slurry delivery system where contact with a surfactant containing slurry is made since it has been found to have the best resistant to abrasive sedimentation and adhesion in surfactant containing slurries. Other suitable dipole inactive materials for contacting a surfactant containing slurry in a CMP slurry delivery system include polyvinylidene fluoride (PVDF), polyethylene, and polypropylene.

In an exemplary embodiment, the surfactant containing slurry is a high selectivity slurry for an STI CMP process for polishing a layer of silicon dioxide overlying an STI trench. By the term high selectivity slurry is meant a slurry containing an abrasive metal oxide that has a material removal rate higher than silica (SiO₂). The high selectivity slurry preferably includes at least one metal oxide as the abrasive, for example ceria (e.g. CeO₂), manganese oxide (e.g., MnO₂, Mn₂O₃, Mn₃O₄), or a combination thereof. The slurry, for example, has a solids content of about 1 weight percent to about 20 weight percent, more preferably, about 5 to about 10 weight percent. Further, the metal oxides preferably have a mean particle diameter ranging from about 20 nanometers to about 500 nanometers, more preferably, about 100 to about 300 nanometers. The high selectivity metal oxide slurry preferably has a particle size distribution with greater than 90 percent of the particles having a particle size of less than about 0.5 microns. The CMP delivery system including dipole inactive materials in contact with the surfactant containing slurry may also include slurries having at least one of silica (SiO₂), alumina (Al₂O₃), ceria (CeO₂), titania (TiO₂), MnO₂, and zirconia (ZrO₂). Preferably, an appropriate amount of surfactant is added to the slurry to inhibit particle agglomeration. The surfactant preferably includes at least one surfactant selected from the group of glycols, aliphatic polyethers, and akoxylated alkyphenols.

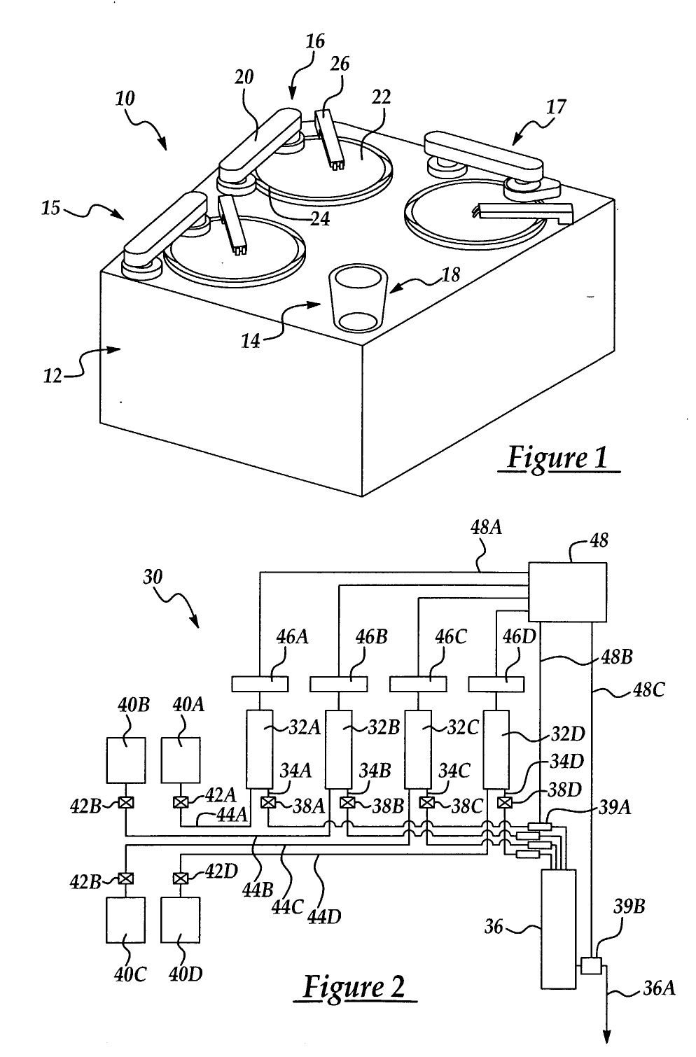

Referring to FIG. 1, in an exemplary CMP system, a plurality of wafers may be polished simultaneously by CMP system 10. The CMP system 10, for example, includes a machine base 12 with a table top 14 supporting a plurality of polishing stations e.g., 15, 16, 17 and a transfer station 18. In operation, the transfer station 18 receives wafers (not shown) from a loader (not shown), washes the wafers, and loads the wafers into carrier head assemblies (not shown) included in a rotatable multi-head carousel (not shown) which fits over the polishing stations to contact the wafers onto polishing pads, e.g., 22. Following the CMP process, the transfer station 18 receives the wafers from the carrier head assemblies, washes the wafers, and transfers the wafers back to the loader.

Each polishing station 15, 16, 17 includes a conventional polishing pad e.g., 22 adhesively attached to a circular platen e.g., 24. Disposed over each polishing station is a liquid feed arm e.g., 26 that projects over the associated polishing pad e.g., 22. The liquid feed arm 26 includes separate supply tubes (not shown) to provide polishing slurry and cleaning liquid, respectively, to the surface of the polishing pad e.g., 22. Each liquid feed arm, e.g., 26 optionally includes several spray nozzles (not shown) to provide a high-pressure rinse at the end of each polishing and conditioning cycle. Each polishing station 15, 16, 17 also includes an optional pad conditioner arm e.g., 20 for pre-conditioning the polishing pads. For example, the various polishing stations may be used for different polishing steps in a sequential CMP polishing procedure. In operation, for example, each carrier head assembly receives a wafer and contacts a polishing pad e.g., 22 of one of the polishing stations 15, 16, 17. The wafer, for example, is simultaneously rotated and linearly moved across the surface of the polishing pad e.g., 32. The slurry delivery system for mixing and delivering a slurry to the liquid feed arms, e.g., 26 may be housed within machine base 12 or a separate housing.

Referring to FIG. 2, a slurry delivery system 30 includes multiple polishing solution containers e.g., 32A, 32B, 32C, 32D, each of which holds a fluidic additive for preparing the polishing solution (slurry). Although four polishing solution containers are shown, fewer or more polishing solution containers can be provided depending on the composition of the slurry to be used in the CMP process. Each polishing solution container e.g., 32A, 32B, 32C, 32D, is in fluidic communication by feed lines 34A, 34B, 34C, 34D with a slurry mixer 36 where the fluidic additives of one or more polishing solution containers are mixed to form the slurry prior to delivering the slurry by feed line 36A to the liquid feed arm e.g., 26 disposed over polishing pad shown e.g., 22 shown in FIG. 1. Flow valves, e.g., 38A, 38B, 38C, 38D are provided along the flow pathway of feed lines 34A, 34B, 34C, 34D, for controllably delivering the various fluidic additives to slurry mixer 36. Optionally, flow meters, e.g., 39A and 39B may be provided along the flow pathway, for example, respectively upstream and downstream of the slurry mixer 36. Each polishing solution container e.g., 32A, 32B, 32C, 32D, is in fluidic communication with a supply container e.g., 40A, 40B, 40C, 40D for re-supplying the additive containers. Another set of flow valves e.g., 42A, 42B, 42C, 42D are provided along the flow pathway of feed lines e.g., 44A, 44B, 44C, 44D, disposed upstream of the polishing solution containers for controllably delivering the various fluidic additives from the supply containers to the polishing solution containers.

Still referring to FIG. 2, preferably a controller 48 controls delivery of fluid to and from polishing solution containers e.g., 32A, 32B, 32C, 32D, by controlling, for example means for controlling a fluidic flow to and from the polishing containers e.g., 46A, 46B, 46C, 46C. For example, the means for controlling a fluidic flow may include a motor or air pressure regulator for controlling a piston (not shown) disposed within the polishing solution containers. It will be appreciated that any means for controlling a fluidic flow from the polishing solution containers may be used. For example, the controller 48 is in electrical communication by electrical communication line e.g., 48A, with the means for controlling a fluidic flow and electrical communication lines 48B and 48C for receiving a flow rate signal from flow meters e.g., 39A and 39B, respectively. In operation, the controller 48 outputs a control signal to means for controlling a fluidic flow e.g., 46A, 46B, 46C, 46C, in response to flow rate signals from flow meters 39A and 39B.

In one embodiment of the present invention, at least that portion of a feed line contacting the surfactant containing slurry is composed of dipole inactive material. For example, the feed lines may include a lining of the dipole inactive material the inner walls of the slurry feed lines. Alternatively, the feed lines may be entirely composed of dipole inactive material.

In another embodiment, apparatus included within a flow pathway of the feed lines include a dipole inactive material for contacting a surfactant containing slurry flow. For example, preferably, at least a portion of the flow pathway within flow meters and flow valves includes dipole inactive material to minimize slurry deposition. For example, at least a portion of the flow pathway is lined with dipole inactive material, for example, having dipole inactive tubing included in the flow pathway.

Preferably, the fluid flow pathways for the surfactant containing slurry including the liquid feed arm (slurry feed arm) for delivering the slurry to the polishing pad includes dipole inactive material along the flow pathways for contacting the surfactant containing slurry. For example, the fluid flow pathways may include dipole inactive tubing inserted within the fluid flow pathways.

Preferably, the mixer, polishing solution containers, and supply containers also include dipole inactive material for contacting the surfactant containing slurry. For example, a fluid contact portion may be composed of dipole inactive material, including, for example, a dipole inactive material lining the fluid contact portion.

The various advantages of the present invention include eliminating the problem of deposition of slurry along the flow pathways of a surfactant containing slurry thereby preventing clogging and contamination and thereby improving the performance of the CMP slurry delivery system. In addition, the mixing precision for the CMP slurry is preserved thereby improving the performance of CMP polishing process including removal rate and polishing uniformity.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A method for preventing deposition of abrasive particles included in a surfactant containing slurry along flow pathways in a chemical mechanical polishing (CMP) slurry delivery system comprising the steps of:
providing a CMP delivery system having one or more flow pathways for delivering a surfactant containing slurry to at least one polishing station the surfactant containing slurry including abrasive particles;
providing at least a fluid contact portion of the one or more flow pathways including at least flow pathway feed lines with a dipole inactive material for contacting the surfactant containing slurry; and,
controllably delivering the surfactant containing slurry along the flow pathway feed lines to the at least one polishing station to perform a CMP process.

2. The method of claim 1, wherein the surfactant has a chemical structure including at least one hydrophilic and at least one hydrophobic chemical group.

3. The method of claim 1, wherein the surfactant includes at least one of glycols, aliphatic polyethers, and akoxylated alkyphenols.

4. The method of claim 1, wherein the abrasive particles include at least one of cerium oxide, manganese oxide, zirconium oxide, and titanium oxide.

5. The method of claim 1, wherein the dipole inactive material includes polytetrafluoroethylene.

6. The method of claim 1, wherein the dipole inactive material includes at least one of polyvinylidene fluoride, polyethylene, and polypropylene.

7. The method of claim 1, wherein the fluid contact portion of the one or more flow pathways further includes at least a portion of at least one of slurry mixers, flow valves, flow meters, and slurry supply arms.

8. The method of claim 1, wherein the flow pathway feed lines include dipole inactive tubing.

9. The method of claim 1, wherein the CMP process includes planarizing a semiconductor surface overlying a shallow trench isolation feature.

10. The method of claim 1, wherein the step of providing a CMP slurry delivery system includes providing a plurality of polishing solution containers each in series fluidic communication with a respective supply container and each polishing solution container in parallel fluidic communication with a mixing container for mixing the surfactant containing slurry.

11. A CMP slurry delivery system for preventing deposition of abrasive particles included in a surfactant containing slurry along delivery flow pathways comprising:
one or more polishing solution containers having respective first flow pathways in parallel fluidic communication with a mixing container for mixing a surfactant containing slurry said mixing container having a second flow pathway in series fluidic communication with a slurry delivery member for delivering the surfactant containing slurry to contact a polishing pad at least a portion of at least one of said first flow pathways and said second flow pathway including a dipole inactive material for contacting the surfactant containing slurry to prevent particle deposition.

12. The CMP slurry delivery system of claim 11, wherein the dipole inactive material includes polytetrafluoroethylene.

13. The CMP slurry delivery system of claim 11, wherein the dipole inactive material includes at least one of polyvinylidene fluoride, polyethylene, and polypropylene.

14. The CMP slurry delivery system of claim 11, wherein the at least one of the first flow pathways and second flow pathway includes at least one flow meter having a flow meter flow pathway wherein at a least a portion of the flow meter flow pathway contacting the surfactant containing slurry is composed of a dipole inactive material.

15. The CMP slurry delivery system of claim 14, wherein the CMP delivery system includes a controller for controlling a flow rate along the at least one of the first flow pathways and second flow pathway in response to a flow rate signal from the at least one flow meter.

16. The CMP slurry delivery system of claim 11, wherein the at least one of the first flow pathways and second flow pathway includes at least one flow valve having a flow valve flow pathway wherein at a least a portion of the flow valve flow pathway contacting the surfactant containing slurry is composed of a dipole inactive material.

17. The CMP slurry delivery system of claim 11, wherein at least a portion of the mixing container contacting the surfactant containing slurry is composed of a dipole inactive material.

18. The CMP slurry delivery system of claim 11, wherein at least a portion of the slurry delivery member contacting the surfactant containing slurry is composed of a dipole inactive material.

19. The CMP slurry delivery system of claim 11, the at least one of the first flow pathways and second flow pathway includes respective feed lines composed of dipole inactive material.

20. The CMP slurry delivery system of claim 11, wherein the surfactant containing slurry includes at least one of glycols, aliphatic polyethers, and akoxylated alkyphenols.
